(19) United States
(12) Patent Application Publication
(10) Pub. No.: US 2026/0333624 A1
(43) Pub. Date: Oct. 22, 2026

(54) TRANSCEIVER DEVICE LIQUID COOLING SYSTEM

(71) Applicant: Dell Products L.P., Round Rock, TX (US)

(72) Inventors: Padmanabhan Narayanan, Chennai (IN); Per Henrik Fremrot, Novato, CA (US); Neal Beard, Austin, TX (US); Vamshidhar Varre, Hyderabad (IN)

(21) Appl. No.: 19/181,479

(22) Filed: Apr. 17, 2025

(51) Int. Cl. H05K 7/20; G06F 1/20

(52) U.S. Cl. CPC H05K 7/20272; G06F 1/20

(57) ABSTRACT

A transceiver device liquid cooling system includes a transceiver device with a heat transfer plate having transceiver device liquid inlet and outlet connectors, and a computing device including a transceiver device port. Computing device liquid inlet and outlet connectors are located adjacent the transceiver device port, and engage the transceiver device liquid inlet and outlet connectors, respectively, when the transceiver device is connected to the transceiver device port. A liquid cooling system is coupled to the computing device liquid inlet and outlet connectors, and circulates a liquid through the heat transfer plate included on the transceiver device when the transceiver device is connected to the transceiver device port to engage the transceiver device liquid inlet and outlet connectors with the computing device liquid inlet and outlet connectors, respectively.

### BACKGROUND

The present disclosure relates generally to information handling systems, and more particularly to liquid cooling transceiver devices used by information handling systems.

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems such as, for example, networking devices (e.g., switch devices), server devices, storage systems, and/or other computing devices known in the art, sometimes utilize transceiver devices connected to their networking ports to transmit data. To provide a specific example, relatively high-power transceiver devices connected to networking ports on the computing devices discussed above may be utilized to support Artificial Intelligence/Machine Learning (AI/ML) fabrics and/or other AI/ML deployments by providing 800 G networking speeds, and are expected to move to 1.6 T and higher networking speeds in the future. However, the provisioning of such networking speeds results in relatively high temperatures in those relatively high-power transceiver devices, which can raise some issues.

For example, conventional solutions to the relatively high temperatures produced by optical transceiver devices in AI/ML systems include the use of air-cooling systems such as optical transceiver device heat sinks, airflow apertures on the surface of the switch devices and airflow channels through the housing of the switch device, and fan devices that generate airflow through the optical transceiver device heat sinks, airflow apertures, and airflow channels to dissipate the heat generated by the optical transceiver devices. However, in such AI/ML systems, the optical transceiver devices discussed above contribute to 40-50% of the power consumption, while the fan devices used in the air-cooling systems discussed above contribute to 15-20% of the power consumption, and it is desirable to reduce the power consumption of such systems, particularly for end-to-end AI/ML system providers.

One conventional solution to such issues has been to use liquid cooling systems to cool transceiver devices utilized in switch devices. However, such conventional liquid cooling systems operate by providing a heat transfer plate (e.g., a “cold” plate) that engages all of the transceiver device cages that are configured to house a row of transceiver devices on the switch device (e.g., a heat transfer plate will extend across all the transceiver device cages that provide a “top” row of transceiver device ports, and a heat transfer plate will extend across all the transceiver device cages that provide a “bottom” row of transceiver device ports). As will be appreciated by one of skill in the art in possession of the present disclosure, the use of a heat transfer plate that engages all of the transceiver devices cages that are configured to house a row of transceiver devices on the switch device is inefficient, as it provides the same cooling to relatively high-power transceiver devices (e.g., Octal Small Form-factor Pluggable (OSFP) transceiver devices) and relatively low-power transceiver devices (e.g., Direct Attach Cable (DAC) transceiver devices) that may be provided in the transceiver device cages, provides more cooling surface than is necessary by having its cooling surface extend across gaps between the transceiver device cages, provides cooling to transceiver device cages even when no transceiver devices are present in those transceiver device cages, and presents other issues that would be apparent to one of skill in the art in possession of the present disclosure.

Accordingly, it would be desirable to provide a transceiver device liquid cooling system that addresses the issues discussed above.

### SUMMARY

According to one embodiment, an Information Handling System (IHS) includes a chassis: a first transceiver device port that is included on the chassis; a first chassis liquid inlet connector that is located adjacent the first transceiver device port and that is configured to engage a first transceiver device liquid inlet connector on a first heat transfer plate included on a first transceiver device when the first transceiver device is connected to the first transceiver device port; a first chassis liquid outlet connector that is located adjacent the first transceiver device port and that is configured to engage a first transceiver device liquid outlet connector on the first heat transfer plate included on the first transceiver device when the first transceiver device is connected to the first transceiver device port; and a liquid cooling system that is coupled to the first chassis liquid inlet connector and the first chassis liquid outlet connector, and that is configured to circulate a liquid through the first heat transfer plate included on the first transceiver device when the first transceiver device is connected to the first transceiver device port to engage the first transceiver device liquid inlet connector with the first chassis liquid inlet connector and engage the first transceiver device liquid outlet connector with the first chassis liquid outlet connector.

### BRIEF DESCRIPTION OF THE DRAWINGS

FIG. 1 is a schematic view illustrating an embodiment of an Information Handling System (IHS).

FIG. 2A is a top schematic view illustrating an embodiment of a computing device that may be provided in the transceiver device liquid cooling system of the present disclosure.

FIG. 2B is a front schematic view illustrating an embodiment of the computing device of FIG. 2A.

FIG. 2C is a top schematic view illustrating an embodiment of the computing device of FIGS. 2A and 2B.

FIG. 2D is a top schematic view illustrating an embodiment of the computing device of FIGS. 2A, 2B, and 2C.

FIG. 2E is a side schematic view illustrating an embodiment of the computing device of FIGS. 2A, 2B, 2C, and 2D.

FIG. 3A is a side schematic view illustrating an embodiment of a transceiver device that may be provided in the transceiver device liquid cooling system of the present disclosure.

FIG. 3B is a top schematic view illustrating an embodiment of the transceiver device of FIG. 3A.

FIG. 3C is a rear schematic view illustrating an embodiment of the transceiver device of FIGS. 3A and 3B.

FIG. 4 is a flow chart illustrating an embodiment of a method for liquid cooling transceiver devices.

FIG. 5A is a schematic view illustrating an embodiment of the transceiver device of FIGS. 3A-3C being coupled to the computing device of FIGS. 2A-2E during the method of FIG. 4.

FIG. 5B is a schematic view illustrating an embodiment of the transceiver device of FIGS. 3A-3C coupled to the computing device of FIGS. 2A-2E during the method of FIG. 4.

FIG. 6A is a schematic view illustrating an embodiment of transceiver devices of FIGS. 3A-3C coupled to the computing device of FIGS. 2A-2E during the method of FIG. 4.

FIG. 6B is a schematic view illustrating an embodiment of transceiver devices of FIGS. 3A-3C coupled to the computing device of FIGS. 2A-2E during the method of FIG. 4.

FIG. 6C is a schematic view illustrating an embodiment of transceiver devices of FIGS. 3A-3C coupled to the computing device of FIGS. 2A-2E during the method of FIG. 4.

FIG. 6D is a schematic view illustrating an embodiment of transceiver devices of FIGS. 3A-3C coupled to the computing device of FIGS. 2A-2E during the method of FIG. 4.

FIG. 7 is a schematic view illustrating an embodiment of the computing device and transceiver devices of FIG. 6C operating during the method of FIG. 4.

FIG. 8A is a schematic view illustrating an embodiment of the computing device and transceiver devices of FIG. 6D operating during the method of FIG. 4.

FIG. 8B is a schematic view illustrating an embodiment of one of the transceiver devices of FIG. 8A operating during the method of FIG. 4.

FIG. 8C is a schematic view illustrating an embodiment of one of the transceiver devices of FIG. 8A operating during the method of FIG. 4.

FIG. 8D is a schematic view illustrating an embodiment of the computing device and transceiver devices of FIG. 6D operating during the method of FIG. 4.

FIG. 9 is a schematic view illustrating an embodiment of a computing device that may be provided in the transceiver device liquid cooling system of the present disclosure.

FIG. 10 is a schematic view illustrating an embodiment of a computing device that may be provided in the transceiver device liquid cooling system of the present disclosure.

FIG. 11 is a schematic view illustrating an embodiment of a liquid cooling safety subsystem that may be provided in the transceiver device liquid cooling system of the present disclosure.

### DETAILED DESCRIPTION

For purposes of this disclosure, an information handling system may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (e.g., desktop or laptop), tablet computer, mobile device (e.g., personal digital assistant (PDA) or smart phone), server (e.g., blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

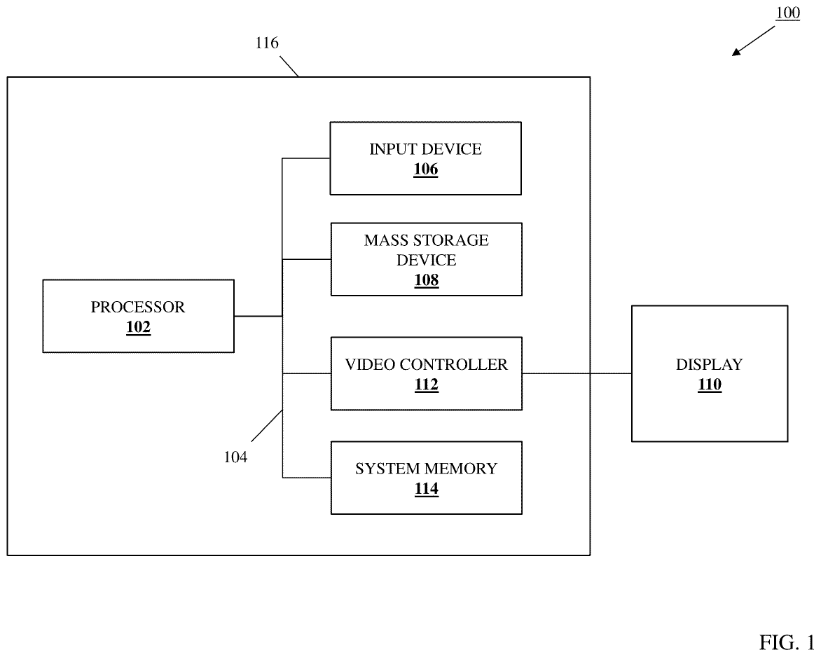

In one embodiment, IHS 100, FIG. 1, includes a processor 102, which is connected to a bus 104. Bus 104 serves as a connection between processor 102 and other components of IHS 100. An input device 106 is coupled to processor 102 to provide input to processor 102. Examples of input devices may include keyboards, touchscreens, pointing devices such as mouses, trackballs, and trackpads, and/or a variety of other input devices known in the art. Programs and data are stored on a mass storage device 108, which is coupled to processor 102. Examples of mass storage devices may include hard discs, optical disks, magneto-optical discs, solid-state storage devices, and/or a variety of other mass storage devices known in the art. IHS 100 further includes a display 110, which is coupled to processor 102 by a video controller 112. A system memory 114 is coupled to processor 102 to provide the processor with fast storage to facilitate execution of computer programs by processor 102. Examples of system memory may include random access memory (RAM) devices such as dynamic RAM (DRAM), synchronous DRAM (SDRAM), solid state memory devices, and/or a variety of other memory devices known in the art. In an embodiment, a chassis 116 houses some or all of the components of IHS 100. It should be understood that other buses and intermediate circuits can be deployed between the components described above and processor 102 to facilitate interconnection between the components and the processor 102.

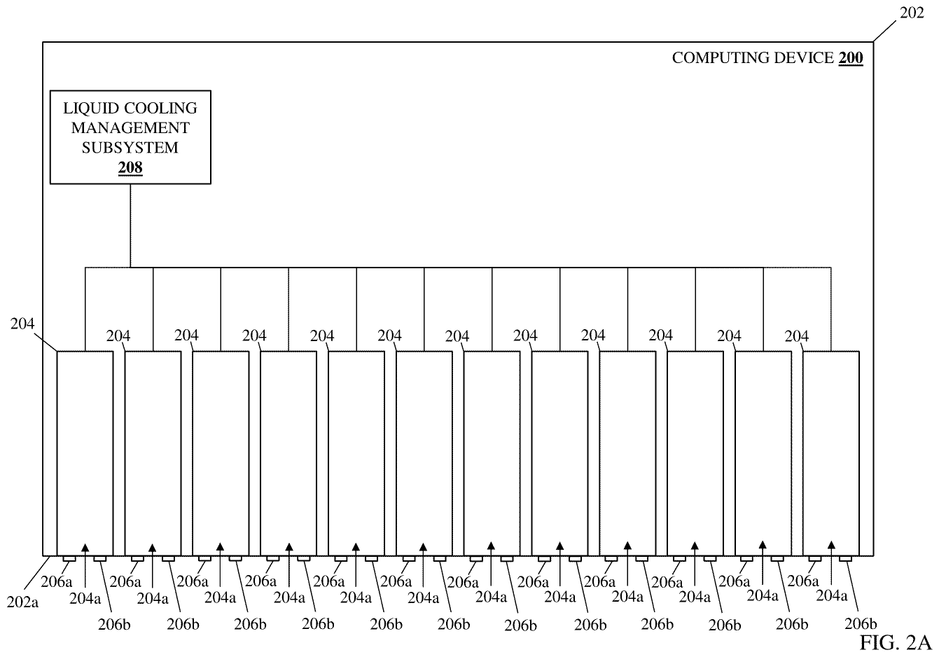

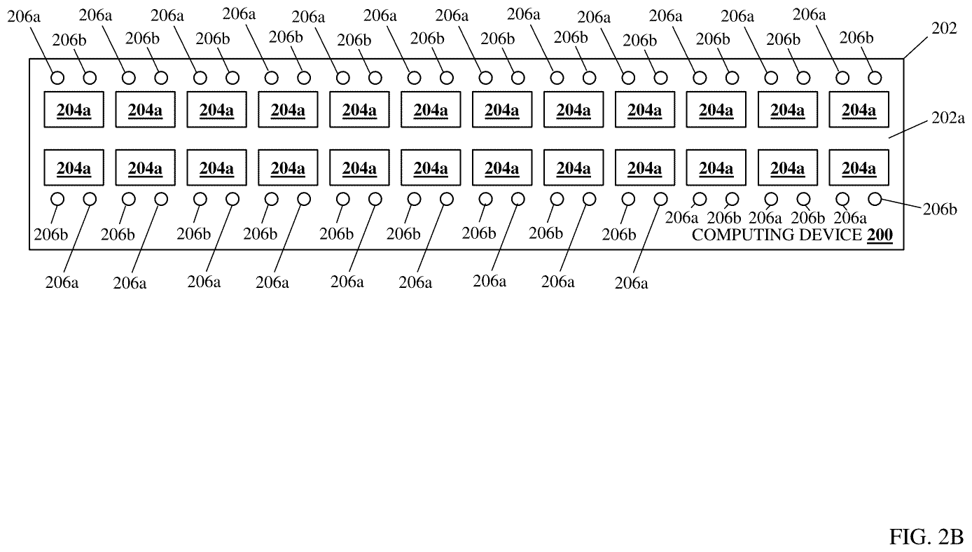

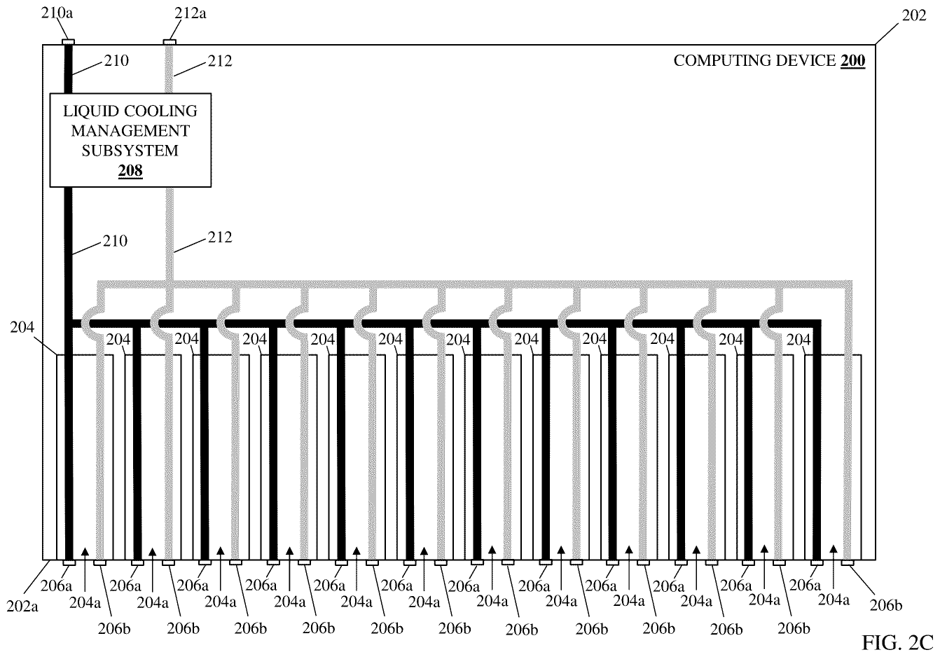

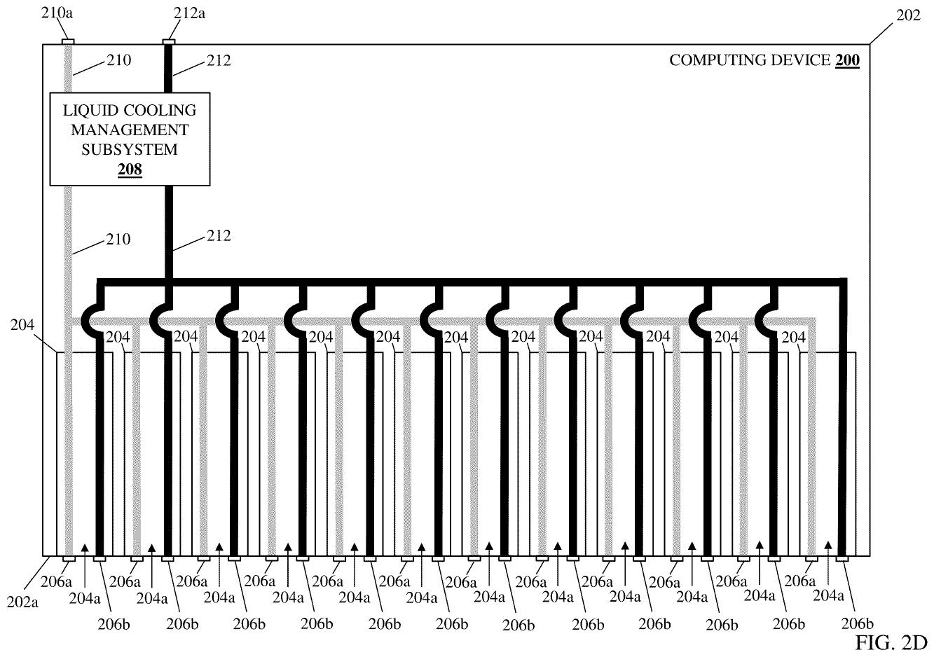

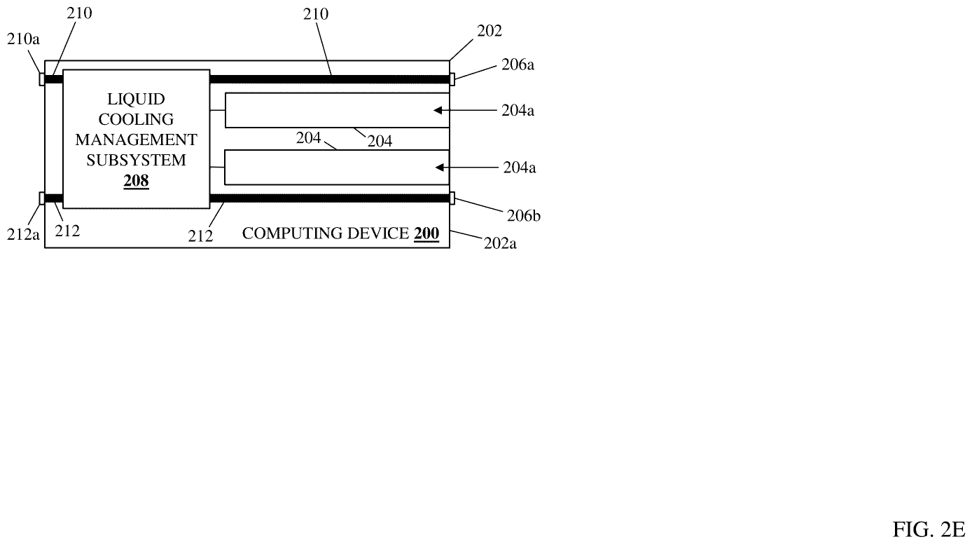

Referring now to FIGS. 2A, 2B, 2C, 2D, and 2E, an embodiment of a computing device 200 is illustrated that may be provided in the transceiver device liquid cooling system of the present disclosure. In an embodiment, the computing device 200 may be provided by the IHS 100 discussed above with reference to FIG. 1 and/or may include some or all of the components of the IHS 100, and one of skill in the art in possession of the present disclosure will appreciate how the computing device 200 illustrated and described in the examples below is provided by a switch device. However, while illustrated and discussed as being provided by a switch device, one of skill in the art in possession of the present disclosure will recognize that the functionality of the computing device 200 discussed below may be provided by other networking devices, storage systems, server devices, and/or other computing devices that are configured to operate similarly as the computing device 200 discussed below.

In the illustrated embodiment, the computing device 200 includes a chassis 202 that houses the components of the computing device 200, only some of which are illustrated and described below. As illustrated in FIGS. 2A and 2B, a plurality of transceiver device cages 204 are housed in the chassis 202 and each provide a respective transceiver device port 204a that is accessible on a “front” surface 202a of the chassis 202, with the specific example provided herein including a “top” row of twelve transceiver device ports, and a “bottom” row of twelve transceiver device ports. While not illustrated, one of skill in the art in possession of the present disclosure will appreciate how each of the transceiver device cages 204 may include a computing device connector (e.g., located at a rear of the transceiver device cage 204 opposite the front surface 202a of the chassis 202) that is configured to connect to a transceiver device connector on a transceiver device as described in further detail below. Furthermore, while the computing device 200 is illustrated and described as including twelve transceiver device port cages that provide each row of twelve transceiver device ports, one of skill in the art in possession of the present disclosure will appreciate how computing devices included in the transceiver device liquid cooling system of the present disclosure may include more or fewer transceiver device ports while remaining within the scope of the present disclosure as well.

As will be appreciated by one of skill in the art in possession of the present disclosure, the height required for the transceiver device ports 204a provided by the transceiver cages 204 will vary depending on the type of transceiver devices used. To provide a specific example, for Quad Small Form-factor Pluggable (QSFP)-type transceiver devices and their variants, the height of the transceiver device ports 204a provided by the transceiver cages 204 may be increased relative to the height of conventional transceiver device ports for QSFP-type transceiver devices by the height of the heat transfer plate (e.g., 2 millimeters) that is provided on those QSFP transceiver devices according to the teachings of the present disclosure.

To provide another specific example, for Octal Small Form-factor Pluggable (OSFP)-type transceiver devices and their variants that are conventionally configured with a finned-heat sink that is housed in the transceiver device cage when the OSFP-type transceiver device is connected to the transceiver device port, the height of the transceiver device ports 204a provided by the transceiver cages 204 may be provided the same as the height of conventional transceiver device ports for OSFP-type transceiver devices, as the heat transfer plate provided on the OSFP transceiver devices according to the teachings of the present disclosure will fit within the volume previously utilized by finned-heat sinks. However, while the height required for the transceiver device ports 204a for a few specific transceiver devices has been described, one of skill in the art in possession of the present disclosure will appreciate how other types of transceiver devices may necessitate other transceiver device port heights while remaining within the scope of the present disclosure as well.

The chassis 202 may also include a plurality of computing device liquid inlet connectors 206a that are located on the front surface 202a of the chassis 202 and that may be provided by any of a variety of liquid cooling connectors (e.g., “quick connect” female liquid cooling connectors) that would be apparent to one of skill in the art in possession of the present disclosure, with one of each of the computing device liquid inlet connectors 206a located adjacent a respective one of each of the transceiver device ports 204a. The chassis 202 may also include a plurality of computing device liquid outlet connectors 206b that are located on the front surface 202a of the chassis 202 and that may be provided by any of a variety of liquid cooling connectors (e.g., “quick connect” female liquid cooling connectors) that would be apparent to one of skill in the art in possession of the present disclosure, with one of each of the computing device liquid outlet connectors 206b located adjacent a respective one of each of the transceiver device ports 204a.

The chassis 202 may also house a liquid cooling system that includes a liquid cooling management subsystem 208 that, as illustrated in FIGS. 2A and 2E, is electrically coupled to each of the transceiver device cages 204 (e.g., to the computing device connector included in each transceiver device cage as described above). As will be appreciated by one of skill in the art in possession of the present disclosure, the liquid cooling management subsystem 208 may include a processing system (not illustrated, but which may include the processor 102 discussed above with reference to FIG. 1) and a memory system (not illustrated, but which may include the memory 114 discussed above with reference to FIG. 1) that is coupled to the processing system and that includes instructions that, when executed by the processing system, cause the processing system to provide a liquid cooling management engine that is configured to perform the functionality of the liquid cooling management engines and/or liquid cooling management subsystems discussed below.

The liquid cooling system in the chassis 202 may also include a liquid inlet subsystem 210 (as illustrated in bolded black lines in FIGS. 2C and 2E, and bolded grey lines in FIG. 2D) that extends from the liquid cooling management subsystem 208 and is connected a liquid supply system inlet connector 210a and each of the computing device liquid inlet connectors 206a, and a liquid outlet subsystem 212 (as illustrated in bolded black lines in FIGS. 2D and 2E, and bolded grey lines in FIG. 2C) that extends from the liquid cooling management subsystem 208 and is connected a liquid supply system outlet connector 212a and each of the computing device liquid outlet connectors 206b. As will be appreciated by one of skill in the art in possession of the present disclosure, the liquid inlet subsystem 210 and the liquid outlet subsystem 212 may be provided by any liquid cooling conduits known in the art, while the liquid cooling management subsystem 208 may provide liquid cooling conduit connections, pumps, valves (e.g., the solenoid valves described below), and/or other liquid cooling components that one of skill in the art in possession of the present disclosure will recognize as providing the functionality described below.

However, while a simplified configuration for the liquid cooling system (e.g., the liquid management subsystem 208, the liquid inlet subsystem 210 coupled to each of the computing device liquid inlet connectors 206a, and the liquid outlet subsystem 212 coupled to each of the computing device liquid inlet connectors 206a) is illustrated in the examples below, one of skill in the art in possession of the present disclosure will appreciate how a variety of other configurations of the liquid cooling system may be provided to enable the functionality described below. For example, and as discussed below, the liquid cooling management subsystem 208 may provide liquid cooling conduits, pumps, valves, and/or other liquid cooling components that enable independent control of liquid supplied to each of the computing device liquid inlet connectors 206a (or to subsets of the computing device liquid inlet connectors 206a).

As such, while FIGS. 2C and 2D illustrated a specific configuration for supplying liquid to the computing device liquid inlet connectors 206a and exhausting liquid from the computing device liquid outlet connectors 206b provided for the “top” row of transceiver device ports 204a, one of skill in the art in possession of the present disclosure will appreciate how liquid may be supplied to the computing device liquid inlet connectors 206a and exhausted from the computing device liquid outlet connectors 206b provided for the “bottom” row of transceiver device ports 204a similarly as described above while remaining within the scope of the present disclosure.

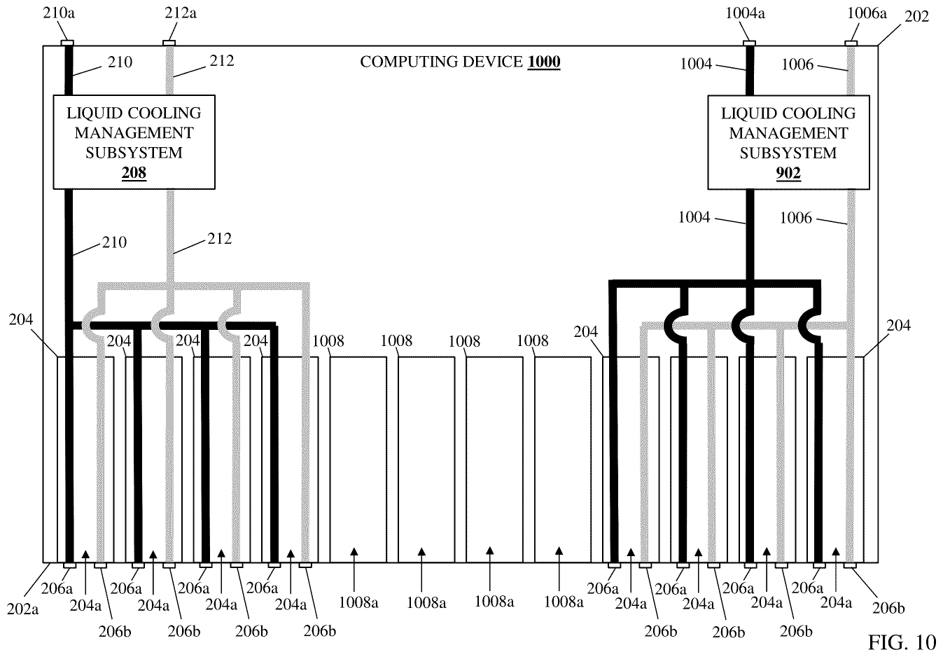

Furthermore, while the simplified examples provided herein may be interpreted as configured to have the liquid inlet subsystem 210 provide cooling liquid under pressure to each of the twelve computing device liquid inlet connectors 206a and enabling the liquid circulation via the transceiver devices and liquid outlet subsystem 212 as described below, one of skill in the art in possession of the present disclosure will appreciate how pump/pressurization capabilities may limit the liquid inlet subsystem 210 to providing cooling liquid under pressure to a maximum number of the computing device liquid inlet connectors 206a (e.g., eight of the computing device liquid inlet connectors 206a) to enable the liquid circulation via the transceiver devices and liquid outlet subsystem 212 as described below, and thus computing devices with relatively high numbers of transceiver device ports may require multiple independent liquid inlet subsystems and corresponding liquid outlet subsystems similarly as described below with reference to FIG. 10. As such, while a specific computing device has been illustrated and described, one of skill in the art in possession of the present disclosure will recognize that computing devices provided in the transceiver device liquid cooling system of the present disclosure may include a variety of components and/or component configurations for providing conventional computing device functionality, as well as the transceiver device liquid cooling functionality discussed below, while remaining within the scope of the present disclosure as well.

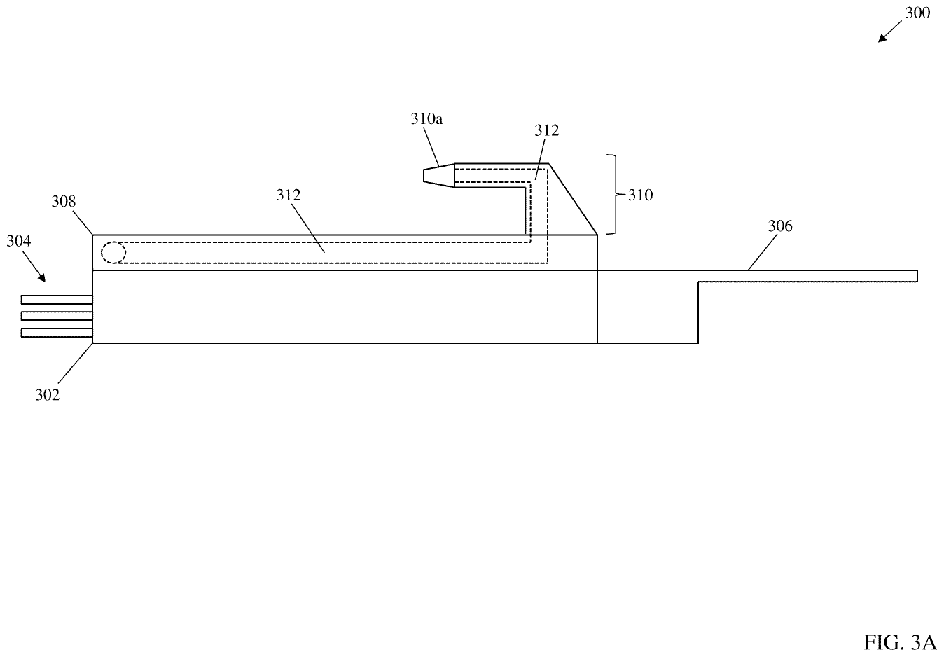

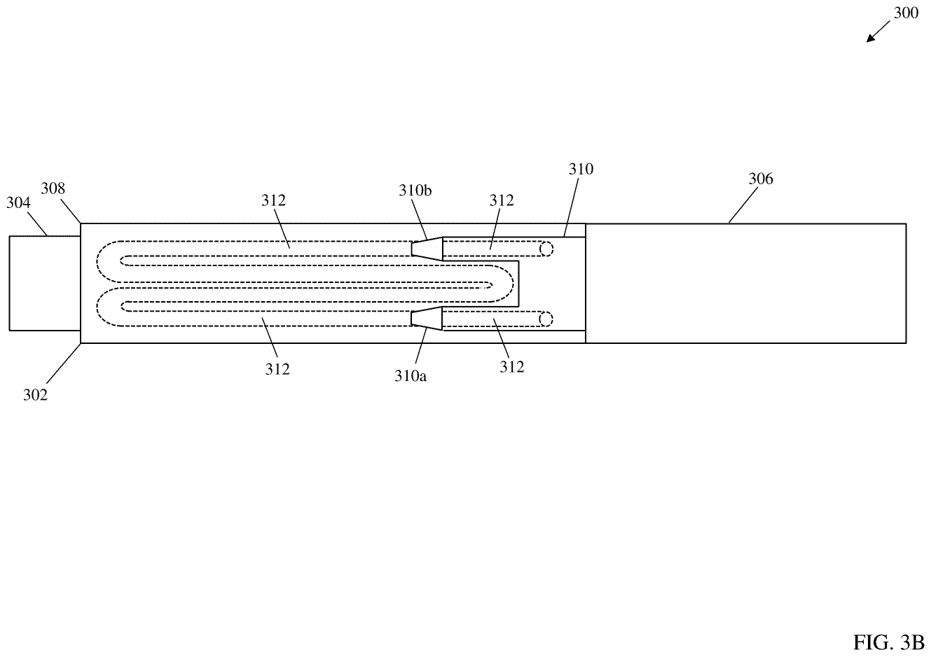

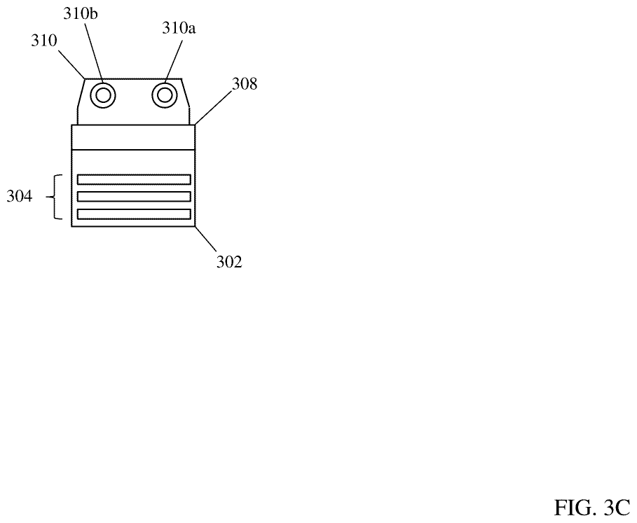

With reference to FIGS. 3A, 3B, and 3C, an embodiment of a transceiver device 300 is illustrated that may be included in the transceiver device liquid cooling system of the present disclosure. The transceiver device 300 includes a transceiver device chassis 302 that houses components of the transceiver device 300 including a circuit board, a processing system, a memory system, communication components, and/or any other transceiver device components that would be apparent to one of skill in the art in possession of the present disclosure. A transceiver device connector 304 extends from a “rear” surface of the chassis 302, and may include any of a variety of transceiver device connectors that would be apparent to one of skill in the art in possession of the present disclosure. A transceiver device handle 306 extends from a “front” surface of the transceiver device chassis 302 and opposite the transceiver device chassis 302 from the transceiver device connector 304.

In the illustrated embodiment, a heat transfer plate 308 (sometimes referred to as a “cold” plate) is mounted to a “top” surface of the transceiver device chassis 302 and extends between the “front” surface and “rear” surface of the transceiver device chassis 302, and may be provided by any of a variety of liquid cooling heat transfer plates that would be apparent to one of skill in the art in possession of the present disclosure. As such, one of skill in the art in possession of the present disclosure will appreciate how the heat transfer plate 308 may be thermally coupled to heat producing components (e.g., the processing system, memory system, communication components, and/or other transceiver device components discussed above) that are housed in the transceiver device chassis 302. A liquid cooling connector system 310 extends from the heat transfer plate 308 and includes a transceiver device liquid inlet connector 310a and a transceiver device liquid outlet connector 310b, each of which may be provided by “quick connect” male liquid cooling connectors and/or other liquid cooling connectors that would be apparent to one of skill in the art in possession of the present disclosure.

As can be seen in FIGS. 3A and 3B, the heat transfer plate 308 and liquid cooling connector system 310 define a transceiver device liquid cooling conduit 312 that extends from the transceiver device liquid inlet connector 310a, through the liquid cooling connector system 310 to the heat transfer plate 308, through the heat transfer plate 308 (e.g., in a serpentine configuration in the illustrated example), back through the through the liquid cooling connector system 310 from the heat transfer plate 308, and to the transceiver device liquid outlet connector 310b. However, while a specific transceiver device liquid cooling conduit configuration is illustrated and described below, one of skill in the art in possession of the present disclosure will appreciate how the transceiver device liquid cooling conduit defined by the heat transfer plate 308 may include a variety of configurations (e.g., other than the specific serpentine configuration illustrated and described herein) while remaining within the scope of the present disclosure as well.

Similarly as discussed above, the height of the transceiver device 300 as measured by the transceiver device chassis 302 and the heat transfer plate 308 will vary depending on the type of the transceiver device 300. For example, when provided by a Quad Small Form-factor Pluggable (QSFP)-type transceiver device and its variants, the height of the transceiver device 300 as measured between the “bottom” of the transceiver device chassis 302 and the “top” of the heat transfer plate 308 will be greater than the height of conventional QSFP-type transceiver devices by the height of the heat transfer plate (e.g., 2 millimeters). However, when provided by a Octal Small Form-factor Pluggable (OSFP)-type transceiver device and its variants that are conventionally configured with a finned-heat sink that is housed in transceiver device cage when the OSFP-type transceiver device is connected to a transceiver device port, the height of the transceiver device 300 as measured between the “bottom” of the transceiver device chassis 302 and the “top” of the heat transfer plate 308 may be the provided to be the same as the height of conventional OSFP-type transceiver devices, as the heat transfer plate 308 may be provided with the same height as the finned-heat sinks discussed above.

However, while a specific transceiver device has been illustrated and described, one of skill in the art in possession of the present disclosure will recognize that transceiver devices provided in the transceiver device liquid cooling system of the present disclosure may include a variety of components and/or component configurations for providing conventional transceiver device functionality, as well as the transceiver device liquid cooling functionality discussed below, while remaining within the scope of the present disclosure as well

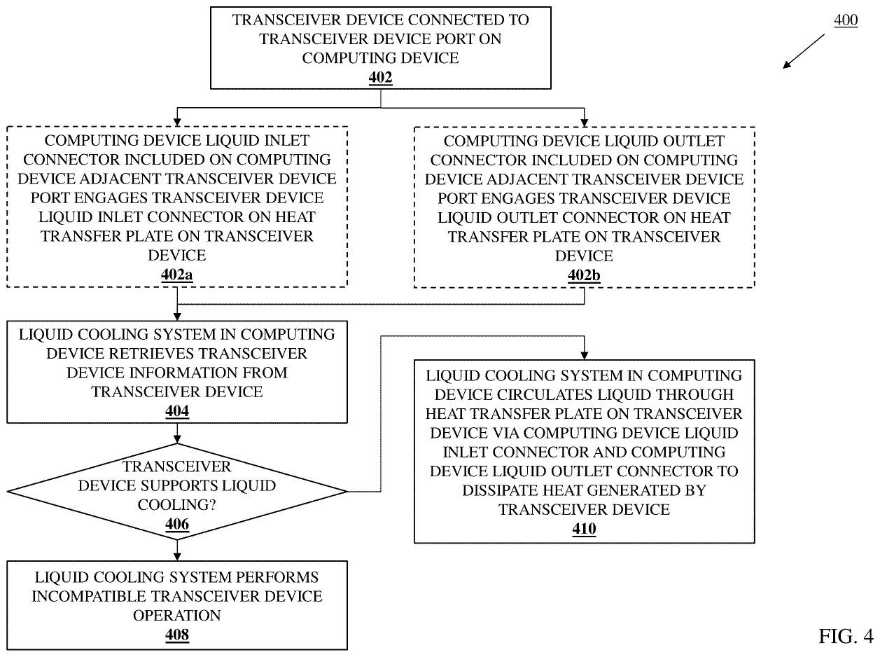

Referring now to FIG. 4, an embodiment of a method 400 for liquid cooling transceiver devices is illustrated. As discussed below, the systems and methods of the present disclosure enable liquid cooling of transceiver devices via respective liquid cooling inlet and outlet couplings that are provided adjacent transceiver device ports and that couple a liquid cooling system to heat transfer plates mounted to transceiver devices that are connected to those transceiver device ports. For example, the transceiver device liquid cooling system of the present disclosure may include a transceiver device with a heat transfer plate having transceiver device liquid inlet and outlet connectors, and a computing device including a transceiver device port. Computing device liquid inlet and outlet connectors are located adjacent the transceiver device port, and engage the transceiver device liquid inlet and outlet connectors, respectively, when the transceiver device is connected to the transceiver device port. A liquid cooling system is coupled to the computing device liquid inlet and outlet connectors, and circulates a liquid through the heat transfer plate included on the transceiver device when the transceiver device is connected to the transceiver device port to engage the transceiver device liquid inlet and outlet connectors with the computing device liquid inlet and outlet connectors, respectively. As such, liquid cooling may be provided for transceiver devices without the inefficiencies of the conventional transceiver device liquid cooling systems described above.

The method 400 begins at block 402 where a transceiver device is connected to a transceiver device port on a computing device. As discussed below, the transceiver device ports 204a on the computing device 200 discussed above with reference to FIGS. 2A-2E are configured to connect to the transceiver device 300 discussed above with reference to FIGS. 3A-3C, but in some situations a user may mistakenly connect a conventional transceiver device (e.g., the conventional air-cooled transceiver devices discussed above) to a transceiver device port 204aon the computing device 200, and the method 400 includes techniques for identifying such mistaken transceiver device connectors and ensuring that they are remedied.

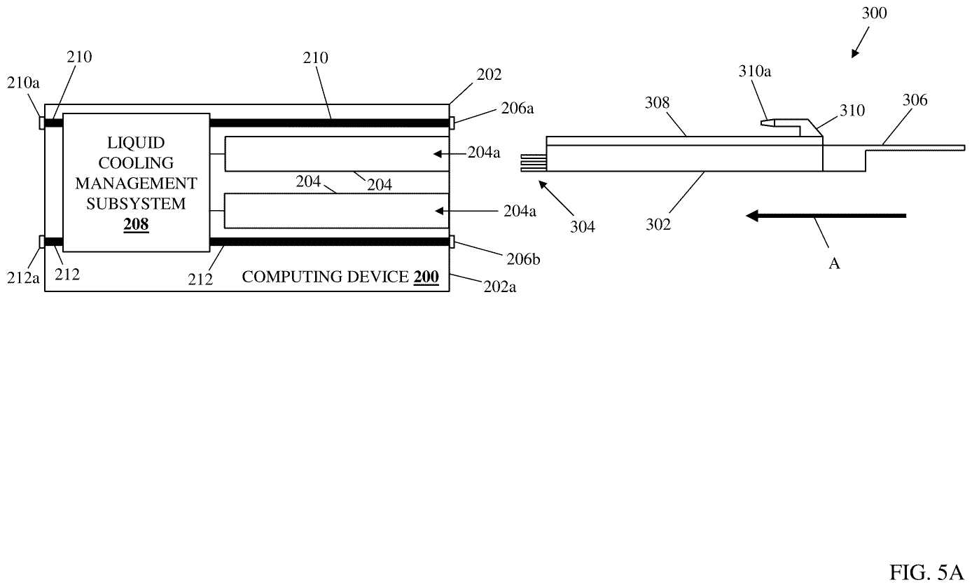

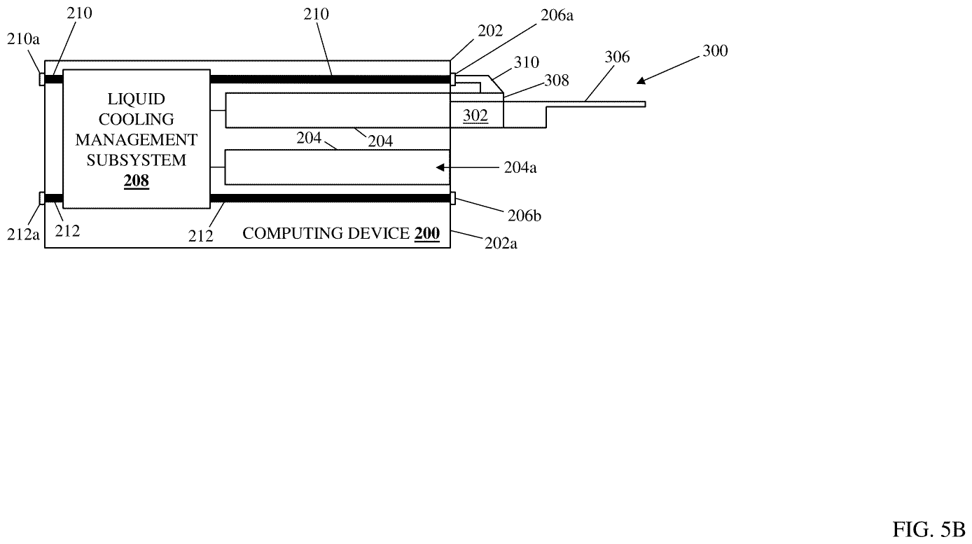

As such, with reference to FIG. 5A and in an embodiment of block 402, the transceiver device 300 may be positioned adjacent the computing device 200 such that the transceiver device connector 304 on the transceiver device 300 is aligned with one of the transceiver device ports 204a. With reference to FIGS. 5A and 5B, the transceiver device 300 may then be moved in a direction A such that the transceiver device connector 304, transceiver device chassis 302, and the heat transfer plate 308 on the transceiver device 300 enter one of the transceiver device cages 204 through its transceiver device port 204a, and one of skill in the art in possession of the present disclosure will appreciate how the transceiver device 300 will move through the transceiver device cage 204 until the transceiver device connector 304 on the transceiver device 300 engages the computing device connector in the transceiver device cage 204 to couple the transceiver device 300 to the liquid cooling management subsystem 208, with the transceiver device chassis 302 and the heat transfer plate 308 on the transceiver device 300 housed in the transceiver device cage 204. Furthermore, while not described in detail, one of skill in the art in possession of the present disclosure will appreciate how a conventional transceiver device (e.g., the conventional air-cooled transceiver devices discussed above) may be mistakenly connected to one of the transceiver device ports 204a on the computing device 200 in a similar manner.

Block 402 of the method 400 may include optional block 402a where a computing device liquid inlet connector included on the computing device adjacent the transceiver device port engages a transceiver device liquid inlet connector on a heat transfer plate on the transceiver device, and optional block 402b where a computing device liquid outlet connector included on the computing device adjacent the transceiver device port engages a transceiver device liquid outlet connector on the heat transfer plate on the transceiver device. For example, and as will be appreciated by one of skill in the art in possession of the present disclosure, in the event a conventional transceiver device (e.g., the conventional air-cooled transceiver devices discussed above) is mistakenly connected to one of the transceiver device ports 204a on the computing device 200 as described above, that conventional transceiver device will not include any liquid cooling subsystem that is configured to connect to the computing device liquid inlet connector 206a and the computing device liquid outlet connector 206b adjacent the transceiver device port 204a to which it was connected, and optional blocks 402a and 402b will be skipped.

However, in embodiments in which the transceiver device 300 is connected to a transceiver device port 204a on the computing device 200, at optional blocks 402a and 402b and during the connection of the transceiver device 300 to the transceiver device port 204a described above with reference to block 402, the transceiver device liquid inlet connector 310a on the liquid cooling connector system 310 included on the transceiver device 300 will engage the computing device liquid inlet connector 206a adjacent the transceiver device port 204a to which it was connected, and the transceiver device liquid outlet connector 310b on the liquid cooling connector system 310 included on the transceiver device 300 will engage the computing device liquid outlet connector 206b adjacent the transceiver device port 204a to which it was connected, and one of skill in the art in possession of the present disclosure will appreciate how optional blocks 402a and 402b may be performed at substantially the same time. As such, following block 402 and optional blocks 402a and 402b, the transceiver device liquid cooling conduit 312 defined by the heat transfer plate 308 and the liquid cooling connector system 310 is fluidly coupled to the liquid inlet subsystem 210 and the liquid outlet subsystem 212 included in the liquid cooling system of the computing device 200.

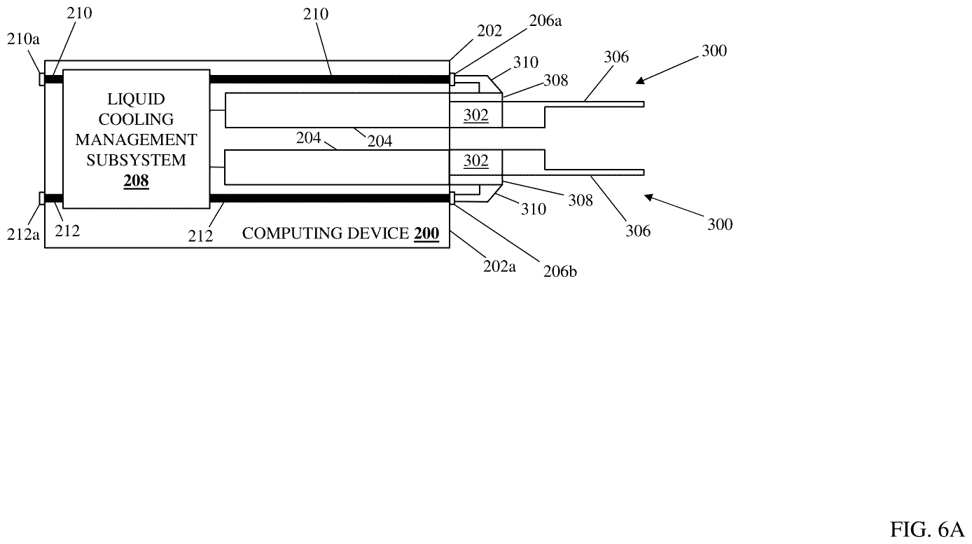

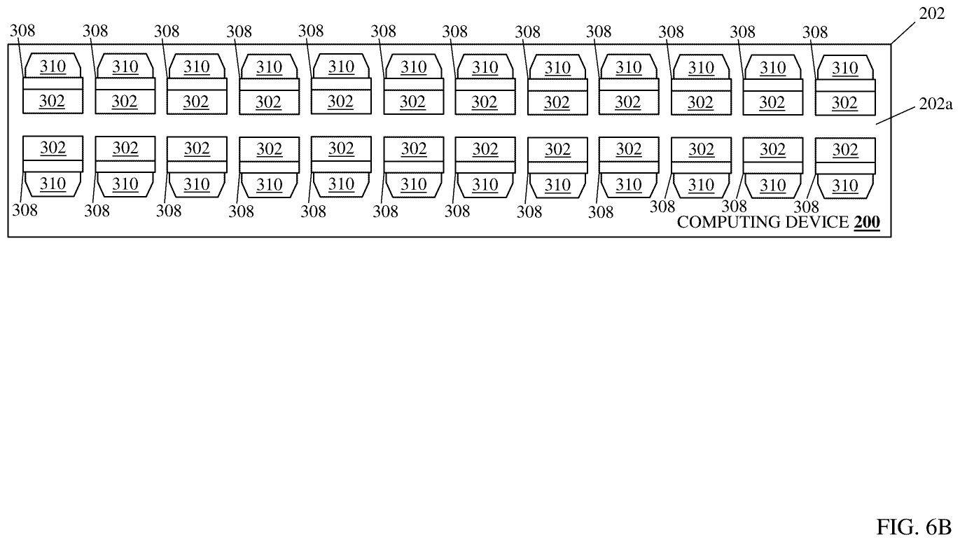

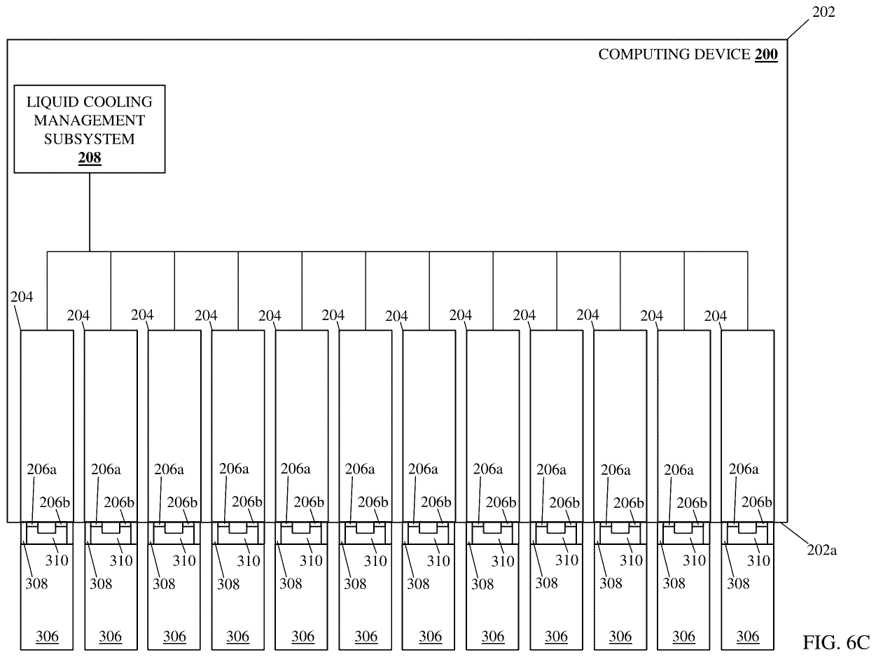

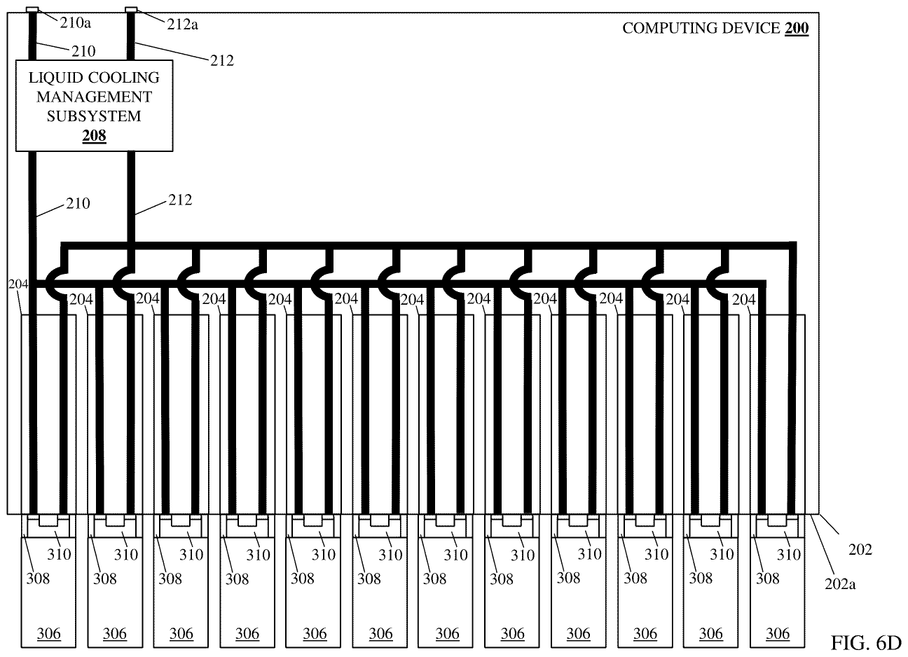

As will be appreciated by one of skill in the art in possession of the present disclosure, FIGS. 5A and 5B illustrates how the transceiver device 300 may be connected to any of the “top” row of transceiver device ports 204a on the computing device 200. FIG. 6A illustrates another one of the transceiver device 300 inverted and connected to one of the transceiver device ports 204a in the “bottom” row of transceiver device ports 204a on the computing device 200, and one of skill in the art in possession of the present disclosure will appreciate how that transceiver device 300/transceiver device port 204a connection may be performed in substantially the same manner as described above with reference to FIGS. 5A and 5B, as well as how the transceiver device 300 may be connected to any of the “bottom” row of transceiver device ports 204a on the computing device 200.

Furthermore, FIGS. 6B-6D illustrate a respective transceiver device 300 connected to each of the transceiver device ports 204a, with FIGS. 6A and 6C illustrating how each of those transceiver devices 300 will be electrically coupled to the liquid cooling management subsystem 208 (e.g., via the connection of its transceiver device connector 304 and the computing device connector in the transceiver cage 204 in which it is housed, as described above), and FIGS. 6A and 6D illustrating how each of those transceiver devices 300 will be fluidly coupled to the liquid cooling system (e.g., via the coupling of its transceiver device liquid cooling conduit 312 (defined by its heat transfer plate 308 and liquid cooling connector system 310) to the liquid inlet subsystem 210 and the liquid outlet subsystem 212 included in the liquid cooling system of the computing device 200, as described above). However, while the specific example provided below includes a respective transceiver device 300 connected to each of the transceiver device ports 204a on the computing device 200, one of skill in the art in possession of the present disclosure will appreciate how only a subset of the transceiver device ports 204a (including only a single transceiver device port 204a) may be populated by respective transceiver devices 300 while remaining within the scope of the present disclosure.

In a specific example of such embodiments in which the transceiver device ports 204a on the computing device are not fully populated, and in embodiments in which the liquid cooling system in the computing device 200 provides the independent, per-transceiver-device control of liquid supply, the liquid cooling management subsystem 208 may prevent liquid from being supplied to the computing device liquid inlet connectors 206a adjacent the transceiver device ports 204a that are not populated with transceiver devices 300 (e.g., by activating solenoid valve(s) to shut off the conduit(s) in the liquid inlet system 210 that provides liquid to the computing device liquid inlet connectors 206a adjacent those transceiver device ports 204a).

However, one of skill in the art in possession of the present disclosure will appreciate how liquid may be prevented from being supplied to the computing device liquid inlet connectors 206a adjacent the transceiver device ports 204a that are not populated with transceiver devices 300 using other techniques (e.g., the computing device liquid inlet connectors 206a may be configured to stop liquid flow when a transceiver device liquid inlet connector 310a is not connected to them) that will fall within the scope of the present disclosure as well. In such an example in which the transceiver device ports 204a on the computing device are not fully populated and the computing device liquid inlet connectors 206a are configured to stop liquid flow when a transceiver device liquid inlet connector 310a is not connected to them, the liquid cooling management subsystem 208 may reduce the pressure of liquid being supplied to the liquid inlet system 210 to a level that allows liquid to circulate through populated transceiver devices without causing the liquid to escape via the computing device liquid inlet connectors 206a.

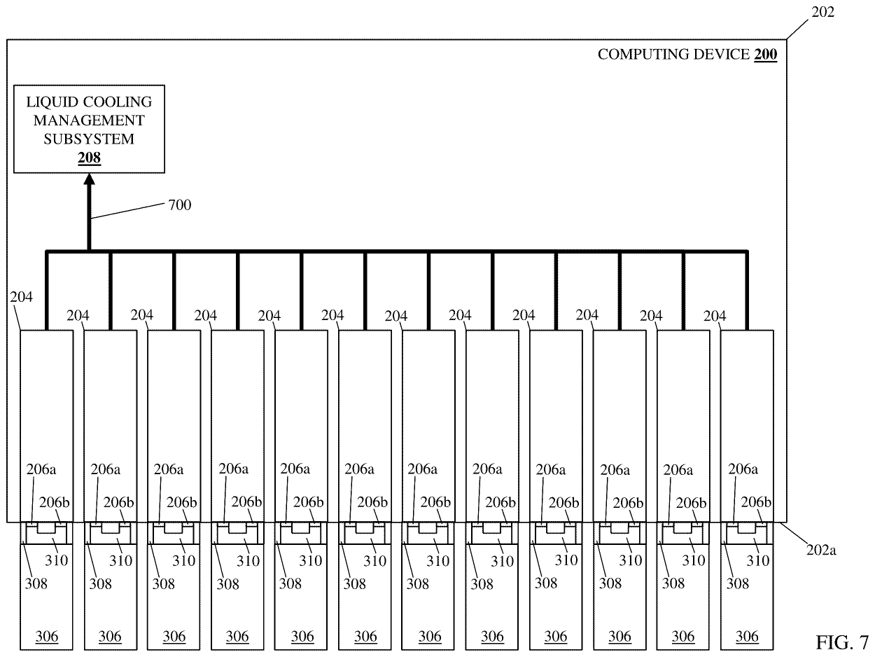

The method 400 then proceeds to block 404 where a liquid cooling system in the computing device retrieves transceiver device information from the transceiver device. With reference to FIG. 7, in an embodiment of block 404 and in response to the transceiver devices 300 being connected to the transceiver device ports 204a at block 402, the liquid cooling management subsystem 208 may perform transceiver device information retrieval operations 700 that include retrieving transceiver device information from each of those transceiver devices 300. For example, at block 404 the transceiver device information retrieval operations 700 performed by the liquid cooling management subsystem 208 may include reading Electronically Erasable Programmable Read-Only Memory (EEPROM) devices in each of the transceiver devices 300 to retrieve transceiver device information about each of those transceiver devices 300 including, for example, an indication of whether that transceiver device 300 supports liquid cooling, information describing the heat generation characteristics/cooling requirements of that transceiver device 300, as well as any other transceiver device information that would be apparent to one of skill in the art in possession of the present disclosure. However, while a specific example has been provided, one of skill in the art in possession of the present disclosure will appreciate how a variety of transceiver device information may be retrieved from the transceiver devices 300 using a variety of techniques that will fall within the scope of the present disclosure.

The method 400 then proceeds to decision block 406 where the method 400 may proceed depending on whether the transceiver device supports liquid cooling. As will be appreciated by one of skill in the art in possession of the present disclosure, following block 404, the liquid cooling management subsystem 208 may store transceiver device information for each transceiver device connected to its transceiver device ports 204a that identifies whether that transceiver device supports liquid cooling (e.g., the transceiver devices 300), or whether that transceiver device does not support liquid cooling (e.g., conventional transceiver device such as the conventional air-cooled transceiver devices discussed above). As such, in an embodiment of decision block 406, the liquid cooling management subsystem 208 may use the transceiver device information retrieved from the transceiver devices connected to the transceiver device ports 204a at block 404 to determine whether those transceiver devise support liquid cooling.

If, at decision block 406, the transceiver device does not support liquid cooling, the method 400 proceeds to block 408 where the liquid cooling system performs an incompatible transceiver device operation. In an embodiment, at block 408 and for each transceiver device that is connected to a transceiver device port 204a and that does not support liquid cooling, the liquid cooling management subsystem 208 may perform incompatible transceiver device operations that may include disabling the transceiver device port 204a to which that transceiver device is connected, generating an incompatible transceiver device warning message for that transceiver device/transceiver device port 204a and providing that incompatible transceiver device warning message for display to a user of the computing device 200 (e.g., via a display on a management device coupled to that computing device 200), activating an incompatible transceiver device alert subsystem such as, for example, activating Light Emitting Devices (LEDs) on the computing device 200 to operate (e.g., “blink”, illuminate in a specific color (e.g., red), etc.) to provide an incompatible transceiver device alert, and/or perform other incompatible transceiver device operations that would be apparent to one of skill in the art in possession of the present disclosure.

In a specific example of incompatible transceiver device operations that may be performed at block 408 and in embodiments in which the liquid cooling system in the computing device 200 provides the independent, per-transceiver-device control of liquid supply, the liquid cooling management subsystem 208 may prevent liquid from being supplied to any transceiver devices that are coupled to the transceiver device ports 204a and that do not support liquid cooling (e.g., by activating solenoid valve(s) to shut off the conduit(s) in the liquid inlet system 210 that provides liquid to the computing device liquid inlet connectors 206a adjacent those transceiver device ports 204a). However, while a specific example has been described, one of skill in the art in possession of the present disclosure will appreciate how liquid may be prevented from being supplied to any transceiver devices that are coupled to the transceiver device ports 204a and that do not support liquid cooling using other techniques (e.g., including preventing liquid from being supplied to transceiver devices that support liquid cooling but that are connected to the same liquid inlet system as the transceiver device(s) that do not support liquid cooling) that will fall within the scope of the present disclosure as well.

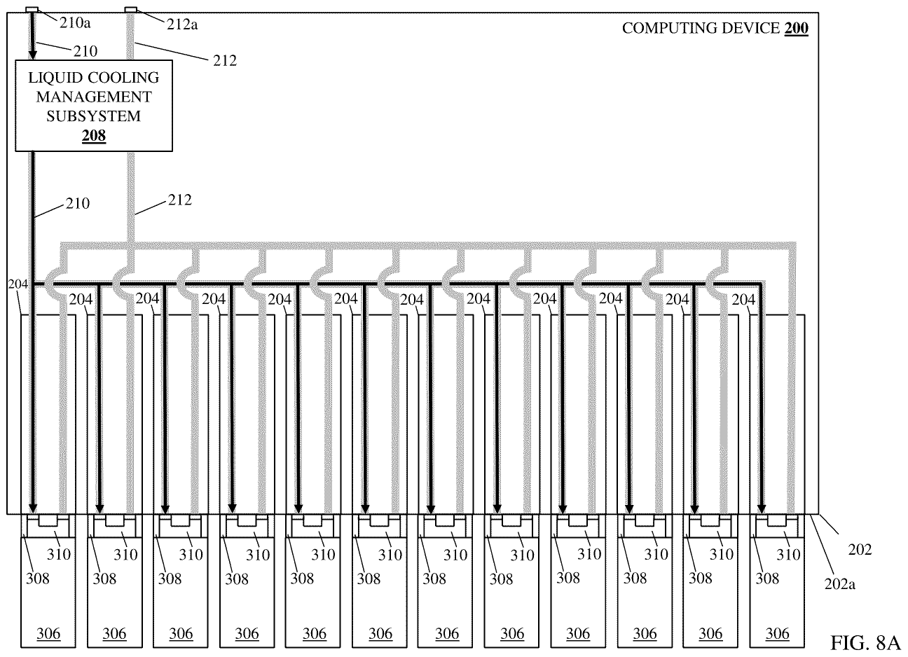

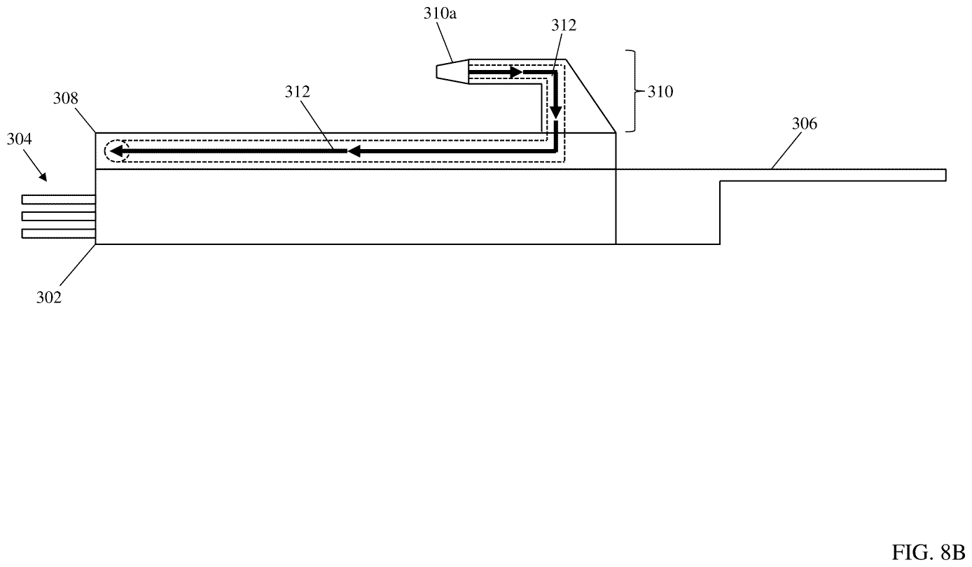

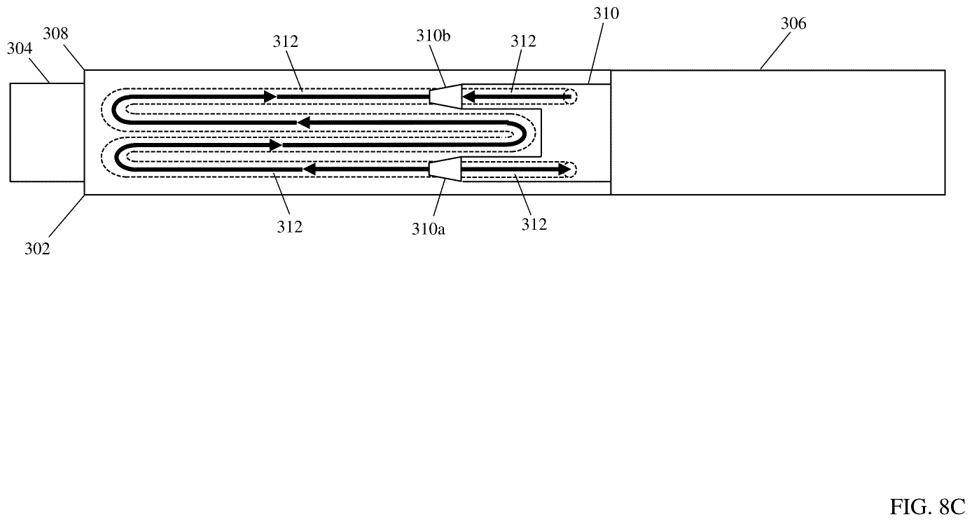

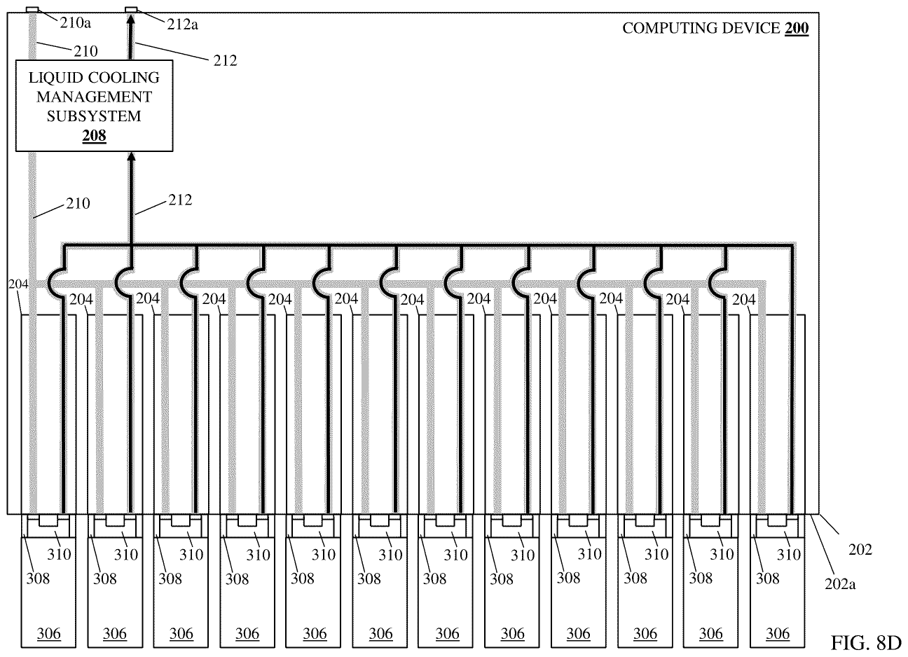

If, at decision block 406, the transceiver device supports liquid cooling, the method 400 proceeds to block 410 where the liquid cooling system in the computing device circulates liquid through the heat transfer plate on the transceiver device via the computing device liquid inlet connector and the computing device liquid outlet connector to dissipate heat generated by the transceiver device. With reference to FIG. 8A, in an embodiment of block 410 and for each transceiver device 300 that is connected to a transceiver device port 204a on the computing device 200 and that supports liquid cooling, the liquid cooling management subsystem 208 may provide cooling liquid from an external liquid supply that is connected to the liquid supply system inlet connector 210a, through the liquid inlet subsystem 210, and to each of the computing device liquid inlet connectors 206a that is provided adjacent a transceiver device port 204a that is connected to a transceiver device 300 that supports liquid cooling.

As illustrated in FIGS. 8B and 8C, at block 410 the cooling liquid that is provided to a computing device liquid inlet connector 206a adjacent a transceiver device port 204a that is connected to a transceiver device 300 that supports liquid cooling will be received via the transceiver device liquid inlet connector 310a connected to that computing device liquid inlet connector 206a and directed through the liquid cooling conduit 312 from the transceiver device liquid inlet connector 310a, through the liquid cooling connector system 310 to the heat transfer plate 308, through the heat transfer plate 308 (e.g., in a serpentine configuration in the illustrated example), back through the through the liquid cooling connector system 310 from the heat transfer plate 308, and to the transceiver device liquid outlet connector 310b. As will be appreciated by one of skill in the art in possession of the present disclosure, the movement of the cooling liquid through the heat transfer plate 308 on a transceiver device 300 will provide for the dissipation of heat generated by transceiver components in the transceiver device 300 by transferring that heat to the cooling liquid to convert it to heated liquid.

As illustrated in FIG. 8D, at block 410, the heated liquid provided to the transceiver device liquid outlet connectors 310b on each transceiver devices 300 that is connected to a transceiver device port 204a on the computing device 200 and that supports liquid cooling will be received via the computing device liquid outlet connector 206b connected to that transceiver device liquid outlet connector 310b and directed through the liquid outlet subsystem 212 and out of the liquid supply system outlet connector 212a to the liquid supply, which one of skill in the art in possession of the present disclosure will appreciate may be configured to remove the heat from that liquid to convert the heated liquid back to cooling liquid that may then again be provided to cool the transceiver devices 300 as described above. As such, the liquid cooling management subsystem 208 may circulate liquid through the transceiver devices 300 as described above to dissipate any heat generated by those transceiver devices 300 during their operation.

In a specific example, and in embodiments in which the liquid cooling system in the computing device 200 provides the independent, per-transceiver-device control of liquid supply, the liquid cooling management subsystem 208 may use the transceiver device information (e.g., the heat generation characteristics/cooling requirements0 retrieved from transceiver devices 300 connected to the transceiver device ports 204a on the computing device 200 to adjust the rate of flow of the cooling liquid to those transceiver devices 300. As such, transceiver devices 300 that generate relatively more heat may be provided higher flow rates of liquid relative to transceiver devices 300 that generate relatively less heat, and one of skill in the art in possession of the present disclosure will appreciate how heat generation by the transceiver devices 300 may be dynamically monitored (e.g., by repeated retrieval of the transceiver device information, using transceiver device operation monitoring techniques known in the art, and/or using other transceiver device heat generation/cooling requirement identification operations that would be apparent to one of skill in the art in possession of the present disclosure) to dynamically adjust the flow rate of the liquid provided to the transceiver devices 300 based on their heat generation/cooling needs.

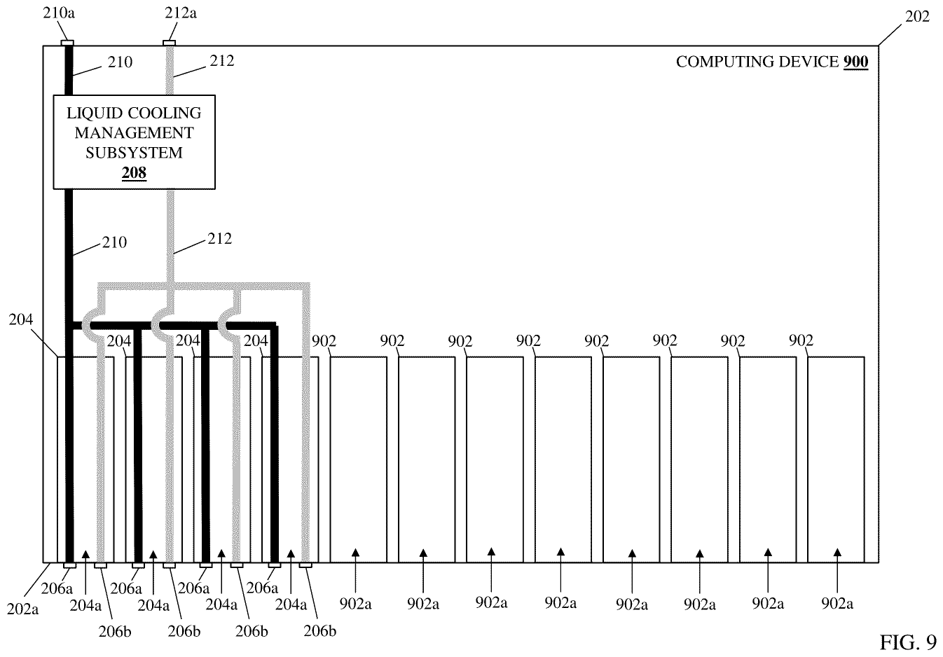

With reference to FIG. 9, an embodiment of a computing device 900 is illustrated that may be included in the transceiver device liquid cooling system of the present disclosure. The computing device 900 is similar to the computing device 200 discussed above, and similar elements have been provided with the same element numbers. However, the computing device 900 differs from the computing device 200 as follows: 1) The liquid inlet subsystem 210 (as illustrated in bolded black lines in FIG. 9) and the liquid outlet subsystem 212 (as illustrated in bolded grey lines in FIG. 9) are only coupled to computing device liquid inlet connector 206a/computing device outlet connector 206b pairs that are located adjacent four of the transceiver device ports 204a (the “left” transceiver device ports 204a in the illustrated example), and 2) the remaining eight of the transceiver device cages 204/transceiver device ports 204a have been replaced with conventional transceiver device cages 902/conventional transceiver device ports 902a.

As will be appreciated by one of skill in the art in possession of the present disclosure, the computing device 900 illustrates how the transceiver device liquid cooling of the present disclosure may be provided for a first subset of transceiver device ports on a computing device (e.g., which may be used with relatively higher power consumption/temperature transceiver devices), with the remaining second subset of transceiver device ports on that computing device cooled conventionally (e.g., and used with relatively lower power consumption/temperature transceiver devices).

With reference to FIG. 10, an embodiment of a computing device 1000 is illustrated that may be included in the transceiver device liquid cooling system of the present disclosure. The computing device 1000 is similar to the computing device 200 discussed above, and similar elements have been provided with the same element numbers. However, the computing device 1000 differs from the computing device 200 as follows: 1) The liquid inlet subsystem 210 (as illustrated in bolded black lines in FIG. 10) and the liquid outlet subsystem 212 (as illustrated in bolded grey lines in FIG. 10) are only coupled to computing device liquid inlet connector 206a/computing device outlet connector 206b pairs that are located adjacent four of the transceiver device ports 204a (the “left” transceiver device ports 204a in the illustrated example), 2) the liquid cooling system in the computing device 1000 includes a liquid cooling management subsystem 1000 that is separate from but substantially similar to the liquid cooling management subsystem 208a, a liquid inlet subsystem 1004 (as illustrated in bolded black lines in FIG. 10) connected to a liquid supply system inlet connector 1004a and to the computing device liquid inlet connectors 206a adjacent four transceiver device ports 204a (the “right” transceiver device ports 204a in the illustrated example), and a liquid outlet subsystem 1006 (as illustrated in bolded grey lines in FIG. 10) connected to a liquid supply system outlet connector 1006a and to the computing device liquid outlet connectors 206b adjacent those four transceiver device ports 204a (the “right” transceiver device ports 204a in the illustrated example), and 3) four of the transceiver device cages 204/transceiver device ports 204a are replaced with conventional transceiver device cages 1008/conventional transceiver device ports 1008a.

As will be appreciated by one of skill in the art in possession of the present disclosure, the computing device 1000 illustrates how the transceiver device liquid cooling of the present disclosure may provide different liquid cooling for different subsets of transceiver device ports on a computing device (e.g., which may be used with relatively higher power consumption/temperature transceiver devices that require different levels of cooling), with a remaining subset of transceiver device ports on that computing device cooled conventionally (e.g., and used with relatively lower power consumption/temperature transceiver devices).

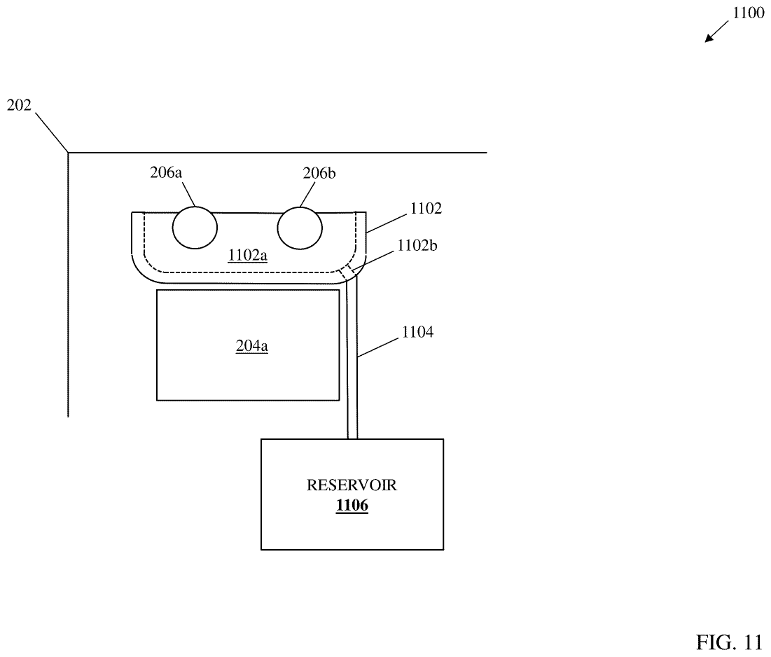

With reference to FIG. 11, an embodiment of a liquid cooling safety subsystem 1100 is illustrated that may be included in the computing device 200 provided in the transceiver device liquid cooling system of the present disclosure. In the illustrated example, the liquid cooling safety subsystem 1100 includes a liquid collection structure 1102 that defines a liquid collection channel 1102a that one of skill in the art in possession of the present disclosure will appreciate may extend from the computing device liquid inlet connector 206a and the computing device liquid outlet connector 206b and along the length of the liquid inlet system 210 and liquid outlet system 212 to the liquid supply system inlet connector 210a and the liquid supply system outlet connector 212. The liquid collection structure 1102 also defines a liquid exit 1102b along with a liquid conduit 1104 that extends to a reservoir 1106 that may be located outside of the computing device 200. As will be appreciated by one of skill in the art in possession of the present disclosure, the liquid collection channel 1102a in the liquid collection structure 1102 may be configured to collect any liquid that leaks from the liquid inlet system 210 and liquid outlet system 212 to prevent that liquid from contacting the transceiver cage 204 or transceiver device 300 included therein, with the liquid exit 1102b and liquid conduit 1104 configured to allow liquid collected by the liquid collection channel 1102a to be channeled out of the computing device 200 to the reservoir 1106.

However, while FIG. 11 illustrates how the liquid cooling safety subsystem 1100 may be used with the liquid inlet system 210/computing device liquid inlet connector 206a and the liquid outlet system 212/computing device liquid outlet connector 206b provided for one of the transceiver device ports 204a, one of skill in the art in possession of the present disclosure will appreciate how the liquid cooling safety subsystem 1100 may be provided by the liquid inlet system 210/computing device liquid inlet connectors 206a and the liquid outlet system 212/computing device liquid outlet connectors 206b provided for a plurality of the transceiver device ports 204a (e.g., respective liquid cooling safety subsystems similar to the liquid cooling safety subsystem 1100 may be provided for the “top” row transceiver device ports 204a and the “bottom ” row transceiver device ports 204a).

Thus, systems and methods have been described that enable liquid cooling of transceiver devices via respective liquid cooling inlet and outlet couplings that are provided adjacent transceiver device ports and that couple a liquid cooling system to heat transfer plates mounted to transceiver devices that are connected to those transceiver device ports. For example, the transceiver device liquid cooling system of the present disclosure may include a transceiver device with a heat transfer plate having transceiver device liquid inlet and outlet connectors, and a computing device including a transceiver device port. Computing device liquid inlet and outlet connectors are located adjacent the transceiver device port, and engage the transceiver device liquid inlet and outlet connectors, respectively, when the transceiver device is connected to the transceiver device port. A liquid cooling system is coupled to the computing device liquid inlet and outlet connectors, and circulates a liquid through the heat transfer plate included on the transceiver device when the transceiver device is connected to the transceiver device port to engage the transceiver device liquid inlet and outlet connectors with the computing device liquid inlet and outlet connectors, respectively. As such, liquid cooling may be provided for transceiver devices without the inefficiencies of the conventional transceiver device liquid cooling systems described above.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A transceiver device liquid cooling system, comprising:
a first transceiver device including a first heat transfer plate having a first transceiver device liquid inlet connector and a first transceiver device liquid outlet connector; and
a computing device including:
a first transceiver device port;
a first computing device liquid inlet connector that is located adjacent the first transceiver device port and that is configured to engage the first transceiver device liquid inlet connector when the first transceiver device is connected to the first transceiver device port;
a first computing device liquid outlet connector that is located adjacent the first transceiver device port and that is configured to engage the first transceiver device liquid outlet connector when the first transceiver device is connected to the first transceiver device port; and
a liquid cooling system that is coupled to the first computing device liquid inlet connector and the first computing device liquid outlet connector, and that is configured to circulate a liquid through the first heat transfer plate included on the first transceiver device when the first transceiver device is connected to the first transceiver device port to engage the first transceiver device liquid inlet connector with the first computing device liquid inlet connector and engage the first transceiver device liquid outlet connector with the first computing device liquid outlet connector.

2. The system of claim 1, wherein the computing device includes:
a first transceiver device cage that provides the first transceiver device port, wherein the first transceiver device and the first heat transfer plate included on the first transceiver device are configured to be housed in the first transceiver device cage when the first transceiver device is connected to the first transceiver device port.

3. The system of claim 1, wherein the computing device includes:
a liquid cooling safety subsystem that is located adjacent the liquid cooling system and that is configured to prevent liquid that escapes from the liquid cooling system from engaging the transceiver device or computing components in the computing device.

4. The system of claim 1, wherein the liquid cooling system is configured to:
retrieve, from the first transceiver device when the first transceiver device is connected to the first transceiver device port, first transceiver device liquid cooling information; and
provide, when the first transceiver device is connected to the first transceiver device port, the liquid via the liquid cooling system to the first computing device liquid inlet connector based on the first transceiver device liquid cooling information.

5. The system of claim 1, wherein the liquid cooling system is configured to:
prevent the liquid from being provided via the liquid cooling system to the first computing device liquid inlet connector when the first transceiver device is not connected to the first transceiver device port.

6. The system of claim 1, further comprising:
a second transceiver device including a second heat transfer plate having a second transceiver device liquid inlet connector and a second transceiver device liquid outlet connector, wherein the computing device includes:
a second transceiver device port;
a second computing device liquid inlet connector that is located adjacent the second transceiver device port and that is configured to engage the second transceiver device liquid inlet connector when the second transceiver device is connected to the second transceiver device port; and
a second computing device liquid outlet connector that is located adjacent the second transceiver device port and that is configured to engage the second transceiver device liquid outlet connector when the second transceiver device is connected to the second transceiver device port, and wherein the liquid cooling system is configured to:
circulate the liquid through the second heat transfer plate included on the second transceiver device when the second transceiver device is connected to the second transceiver device port to engage the second transceiver device liquid inlet connector with the second computing device liquid inlet connector and engage the second transceiver device liquid outlet connector with the second computing device liquid outlet connector.

7. An Information Handling System (IHS), comprising:
a chassis:
a first transceiver device port that is included on the chassis;
a first chassis liquid inlet connector that is located adjacent the first transceiver device port and that is configured to engage a first transceiver device liquid inlet connector on a first heat transfer plate included on a first transceiver device when the first transceiver device is connected to the first transceiver device port;
a first chassis liquid outlet connector that is located adjacent the first transceiver device port and that is configured to engage a first transceiver device liquid outlet connector on the first heat transfer plate included on the first transceiver device when the first transceiver device is connected to the first transceiver device port; and
a liquid cooling system that is coupled to the first chassis liquid inlet connector and the first chassis liquid outlet connector, and that is configured to circulate a liquid through the first heat transfer plate included on the first transceiver device when the first transceiver device is connected to the first transceiver device port to engage the first transceiver device liquid inlet connector with the first chassis liquid inlet connector and engage the first transceiver device liquid outlet connector with the first chassis liquid outlet connector.

8. The IHS of claim 7, further comprising:
a first transceiver device cage that provides the first transceiver device port, wherein the first transceiver device and the first heat transfer plate included on the first transceiver device are configured to be housed in the first transceiver device cage when the first transceiver device is connected to the first transceiver device port.

9. The IHS of claim 7, further comprising:
a liquid cooling safety subsystem that is located adjacent the liquid cooling system and that is configured to prevent liquid that escapes from the liquid cooling system from engaging the transceiver device or computing components in the computing device.

10. The IHS of claim 7, wherein the liquid cooling system is configured to:
retrieve, from the first transceiver device when the first transceiver device is connected to the first transceiver device port, first transceiver device liquid cooling information; and
provide, when the first transceiver device is connected to the first transceiver device port, the liquid via the liquid cooling system to the first chassis liquid inlet connector based on the first transceiver device liquid cooling information.

11. The IHS of claim 7, wherein the liquid cooling system is configured to:
prevent the liquid from being provided via the liquid cooling system to the first chassis liquid inlet connector when the first transceiver device is not connected to the first transceiver device port.

12. The IHS of claim 7, further comprising:
a second transceiver device port;
a second chassis liquid inlet connector that is located adjacent the second transceiver device port and that is configured to engage a second transceiver device liquid inlet connector on a second heat transfer plate included on a second transceiver device when the second transceiver device is connected to the second transceiver device port; and
a second chassis liquid outlet connector that is located adjacent the second transceiver device port and that is configured to engage a second transceiver device liquid outlet connector on the second heat transfer plate included on the second transceiver device when the second transceiver device is connected to the second transceiver device port, and wherein the liquid cooling system is configured to:
circulate the liquid through a second heat transfer plate included on the second transceiver device when the second transceiver device is connected to the second transceiver device port to engage the second transceiver device liquid inlet connector with the second chassis liquid inlet connector and engage the second transceiver device liquid outlet connector with the second chassis liquid outlet connector.

13. The IHS of claim 12, wherein the liquid cooling system is configured to:
independently control a respective flow of the liquid to each of the first chassis liquid inlet connector and the second chassis liquid inlet connector.

14. A method for liquid cooling transceiver devices, comprising:
engaging, by a first computing device liquid inlet connector that is included on a computing device and located adjacent a first transceiver device port that is included on the computing device, a first transceiver device liquid inlet connector on a first heat transfer plate included on a first transceiver device when the first transceiver device is connected to the first transceiver device port;
engaging, by a first computing device liquid outlet connector that is included on the computing device and located adjacent the first transceiver device port, a first transceiver device liquid outlet connector on the first heat transfer plate included on the first transceiver device when the first transceiver device is connected to the first transceiver device port; and
circulating, by a liquid cooling system that is included in the computing device and coupled to the first computing device liquid inlet connector and the first computing device liquid outlet connector, a liquid through the first heat transfer plate included on the first transceiver device when the first transceiver device is connected to the first transceiver device port to engage the first transceiver device liquid inlet connector with the first computing device liquid inlet connector and engage the first transceiver device liquid outlet connector with the first computing device liquid outlet connector.

15. The method of claim 14, further comprising:
housing, by the first transceiver device and the first heat transfer plate included on the first transceiver device, in a first transceiver device cage that provides the first transceiver device port when the first transceiver device is connected to the first transceiver device port.

16. The method of claim 14, further comprising:
preventing, by a liquid cooling safety subsystem that is located adjacent the liquid cooling system, liquid that escapes from the liquid cooling system from engaging the transceiver device or computing components in the computing device.

17. The method of claim 14, further comprising:
retrieving, by the liquid cooling system from the first transceiver device when the first transceiver device is connected to the first transceiver device port, first transceiver device liquid cooling information; and
providing, by the liquid cooling system when the first transceiver device is connected to the first transceiver device port, the liquid via the liquid cooling system to the first computing device liquid inlet connector based on the first transceiver device liquid cooling information.

18. The method of claim 14, further comprising:
preventing, by the liquid cooling system, the liquid from being provided via the liquid cooling system to the first computing device liquid inlet connector when the first transceiver device is not connected to the first transceiver device port.

19. The method of claim 14, further comprising:
engaging, by a second computing device liquid inlet connector that is included on the computing device and located adjacent a second transceiver device port that is included on the computing device, a second transceiver device liquid inlet connector on a second heat transfer plate included on a second transceiver device when the second transceiver device is connected to the second transceiver device port;
engaging, by a second computing device liquid outlet connector that is included on the computing device and located adjacent the second transceiver device port, a second transceiver device liquid outlet connector on a second heat transfer plate included on the second transceiver device when the second transceiver device is connected to the second transceiver device port; and
circulating, by the liquid cooling system that is coupled to the second computing device liquid inlet connector and the second computing device liquid outlet connector, the liquid through the second heat transfer plate included on the second transceiver device when the second transceiver device is connected to the second transceiver device port to engage the second transceiver device liquid inlet connector with the second computing device liquid inlet connector and engage the second transceiver device liquid outlet connector with the second computing device liquid outlet connector.

20. The method of claim 19, further comprising:
independently controlling, by the liquid cooling system, a respective flow of the liquid to each of the first computing device liquid inlet connector and the second computing device liquid inlet connector.
